(19) United States
(12) Patent Application Publication
(10) Pub. No.: US 2006/0291115 A1
(43) Pub. Date: Dec. 28, 2006

(54) Semiconductor integrated circuit device and method of fabricating the same

(75) Inventors: Jae-Ho Song, Suwon-si (KR); Young-Hoon Park, Suwon-si (KR); Eun-Soo Kim, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/472,374

(22) Filed: Jun. 22, 2006

(30) Foreign Application Priority Data
Jun. 23, 2005 (KR) 10-2005-0054564

(51) Int. Cl. H02H 9/00

(52) U.S. Cl. 361/56

(57) ABSTRACT

Provided are a semiconductor integrated circuit (IC) device and a method of fabricating the same. The semiconductor IC device may include first, second and third deep wells of a first conductivity type formed in a semiconductor substrate, and electrically isolated from one another; first and second wells of a second conductivity type and an active pixel sensor (APS) array formed between a top surface of the semiconductor substrate and the first, second and third deep wells, respectively; and first, second and third protective wells of the first conductivity type formed in the semiconductor substrate. The first and second wells of the second conductivity type and the APS array may be connected to different power supply voltages. The first, second and third protective wells of the first conductivity type may surround side surfaces of the first and second wells and the APS array, respectively.

### PRIORITY STATEMENT

This application claims the benefit of priority from Korean Patent Application No. 10-2005-0054564, filed on Jun. 23, 2005, in the Korean Intellectual Property Office, the entire contents of which is incorporated herein by reference.

### BACKGROUND OF THE INVENTION

1. Field of the Invention

Example embodiments of the present invention relate to a semiconductor integrated circuit (IC) device. More particularly, example embodiments of the present invention relate to a semiconductor IC device including an image sensor and a method of fabricating the same.

2. Description of the Related Art

An image sensor may convert optical information into electrical signals. Recently, with the development of computer and communication industries, there is an increasing demand for highly-efficient image sensors in various fields, including digital cameras, camcorders, personal communication systems, game devices, surveillance cameras, microcameras for medical use, robots, etc.

With improvements in performance of system large scale integration (LSI) chip technology, an image sensing circuit, a digital circuit, an analog circuit, etc., may be integrated on a single semiconductor substrate. Each of the digital circuit, analog circuit and image sensing circuit, which may be integrated on the same substrate in a semiconductor integrated circuit (IC) device, may be supplied with a voltage from a different external power supply source in order to reduce electromagnetic interference, which may reduce noise that may be generated due to interference among the respective circuits.

In order to separately supply the digital circuit, the analog circuit and the image sensing circuit with different external power supply sources, the respective circuits may be electrically isolated from one another by forming wells using impurity implantation. In a conventional semiconductor IC device including an image sensor, impurities implanted into the wells may vary according to the conductivity type of a semiconductor substrate, e.g., either a P-type or an N-type. If the same well structure used in a P-type semiconductor substrate is applied to an N-type semiconductor substrate, a short circuit between external power supply sources for supplying power supply voltages to the circuits in the semiconductor IC device may be caused. Accordingly, different well structures should be applied to the P-type semiconductor substrate and the N-type semiconductor substrate. That is, impurities used to form the wells when a P-type semiconductor substrate is used are different from impurities used to form the wells when an N-type semiconductor substrate is used in a conventional semiconductor IC device.

Further, in a conventional semiconductor IC device including an image sensor, even if wells are formed to correspond with the digital, analog and image sensing circuits, because a potential barrier between the respective wells is not high, a problem may occur. One problem is that noise may be caused because a substrate voltage affects the circuits and the circuits mutually affect one another due to external power supply voltages applied thereto.

### SUMMARY OF THE INVENTION

Example embodiments of the present invention provide a semiconductor integrated circuit (IC) device that may be implemented using any of an N-type and a P-type semiconductor substrate and has reduced noise.

Example embodiments of the present invention provide a method of fabricating a semiconductor integrated circuit (IC) device that may be implemented using any of an N-type and a P-type semiconductor substrate and has reduced noise.

An example embodiment of the present invention provides a semiconductor integrated circuit (IC) device. The semiconductor integrated circuit device may include first, second and third deep wells of a first conductivity type formed in a semiconductor substrate, and electrically isolated from one another; first and second wells of a second conductivity type and an active pixel sensor (APS) array formed between a top surface of the semiconductor substrate and the first, second and third deep wells, respectively, and connected to different power supply voltages, respectively; and first, second and third protective wells of the first conductivity type formed in the semiconductor substrate, and surrounding side surfaces of the first and second wells and the APS array, respectively.

An example embodiment of the present invention provides a method of fabricating a semiconductor integrated circuit device. The method may include forming first, second and third deep wells of a first conductivity type formed in a semiconductor substrate so the first, second and third deep wells are electrically isolated from one another; and forming first and second wells of a second conductivity type and an active pixel sensor (APS) array between a top surface of the semiconductor substrate and the first, second and third deep wells, respectively, so that the first and second wells and the APS are surrounded by first, second and third protective wells, respectively, the first and second wells and the APS are connected to different power supply voltages.

### BRIEF DESCRIPTION OF THE DRAWINGS

The above and other features and/or advantages of example embodiments of the present invention will become more apparent by describing in detail example embodiments of the present invention with reference to the attached drawings in which:

FIG. 1 is a block diagram illustrating a semiconductor IC device according to an example embodiment of the present invention;

FIG. 2A is a sectional view illustrating a semiconductor IC device according to an example embodiment of the present invention;

FIG. 2B is a plan view of a semiconductor IC device according to an example embodiment of the present invention shown in FIG. 2;

FIG. 3 is a circuit diagram illustrating each pixel of an image sensing circuit according to an example embodiment of the present invention;

FIG. 4 is a schematic plan view of a pixel according to an example embodiment of the present invention shown in FIG. 3;

FIG. 5 is a cross-sectional view illustrating a pixel of an image sensing circuit, taken along a line V-V′ of FIG. 4 according to an example embodiment of the present invention;

FIGS. 6A through 6C are cross-sectional views illustrating steps in a method of fabricating a semiconductor IC device according to an example embodiment of the present invention;

FIG. 7 is a cross-sectional view illustrating a semiconductor IC device according to an example embodiment of the present invention; and

FIG. 8A to FIG. 8C are cross-sectional views illustrating steps in a method of fabricating a semiconductor IC device according to an example embodiment of the present invention.

### DETAILED DESCRIPTION OF EXAMPLE EMBODIMENTS OF THE PRESENT INVENTION

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the drawings. For example, two FIGS. shown in succession may in fact be executed substantially concurrently or may sometimes be executed in the reverse order, depending upon the functionality/acts involved.

In the FIGS., if a layer is formed on another layer or a substrate, it means that the layer is directly formed on another layer or a substrate, or that a third layer is interposed therebetween.

This invention may be embodied in many different forms and should not be construed as limited to the embodiments set forth herein; rather, these example embodiments of the present invention are provided so that this disclosure will be thorough and complete, and will fully convey the scope of the invention to those skilled in the art. In the drawings, the thickness of layers and regions are exaggerated for clarity, and like numbers refer to like elements throughout. Moreover, the term “conductivity” refers to a particular conductivity type, such as a P-type or an N-type. Each example embodiment of the present invention described and illustrated herein includes complementary embodiments. Like reference numerals refer to like elements throughout the specification.

Image sensors according to example embodiments of the present invention may include a charge coupled device (CCD) image sensor and a complementary metal oxide semiconductor (CMOS) image sensor. A CCD image sensor may have smaller noise and better image quality than a CMOS image sensor. However, a CCD image sensor may require a high voltage and may be relatively expensive to manufacture. A CMOS image sensor may be relatively easy to operate and may be implemented in various scanning methods. Because a signal processing circuit may be integrated with an image sensor on a single chip, smaller products may be produced as a result. In addition, manufacturing costs may be reduced using a CMOS manufacturing technology. Further, due to a CMOS image sensor having a relatively low power consumption, a CMOS image sensor may be easily applied to products having limited battery capacity.

Hereinafter, a semiconductor IC device and a method of fabricating a semiconductor IC device according to example embodiments of the present invention will be described with reference to the accompanying drawings.

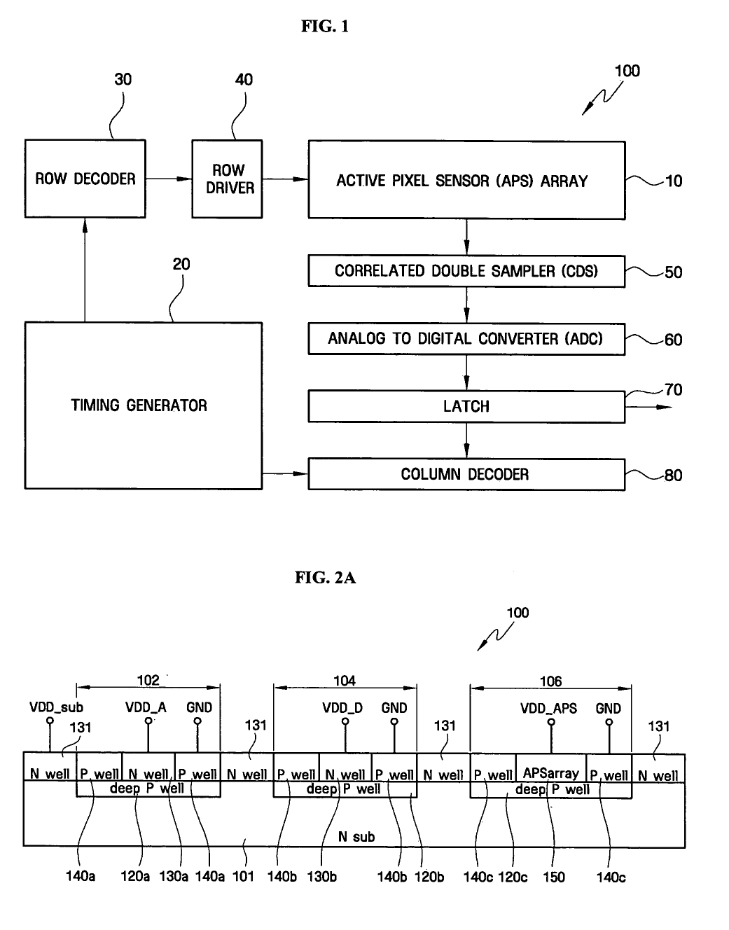

FIG. 1 is a block diagram illustrating a semiconductor IC device 100 according to an example embodiment of the present invention.

Referring to FIG. 1, the semiconductor IC device 100 according to an example embodiment of the present invention may include an active pixel sensor (APS) array 10, a timing generator 20, a row decoder 30, a row driver 40, a correlated double sampler (CDS) 50, an analog-to-digital (ADC) converter 60, a latch 70, and a column decoder 80.

The APS array 10 may include a plurality of pixels arranged in a matrix form. Each of the plurality of pixels may convert an optical image into an electrical signal. The APS array 10 may operate in response to a plurality of driving signals received from the row driver 40. The plurality of driving signals may include a pixel selection signal (ROW), a reset signal (RST), and first and second charge transmission signals TG1 and TG2. The APS array 10 may provide the electrical signal to the CDS 50 via a vertical signal line.

The timing generator 20 may provide a timing signal and a control signal to the row decoder 30 and the column decoder 80, respectively.

The row driver 40 may provide the plurality of driving signals to the APS array 10 to operate the plurality of pixels according to a decoding result of the row decoder 30. Generally, when the pixels are arranged in a matrix form, a driving signal is provided for each row. The CDS 50 may receive the electrical signal from the APS array 10 via the vertical signal line and may perform a sampling and/or holding operation on the received electrical signal. The CDS 50 may double sample a reference voltage level (hereinafter, referred to as a “noise level”) and a voltage level of the electrical signal (hereinafter, referred to as a “signal level”) and may output a differential level corresponding to a difference between the noise level and the signal level.

The ADC 60 may convert an analog signal corresponding to the differential level into a digital signal.

The latch 70 may latch the digital signal, which may be output to an image signal processor (not shown) according to a decoding result of the column decoder 80.

According to an example embodiment of the present invention, the semiconductor IC device 100 may include an analog circuit, a digital circuit and an image sensing circuit. In the semiconductor IC device 100, the analog circuit may include the CDS 50 and the ADC 60; the digital circuit may include the timing generator 20, the row decoder 30, the row driver 40, the latch 70 and the column decoder 80; and the image sensing circuit may include the APS array 10.

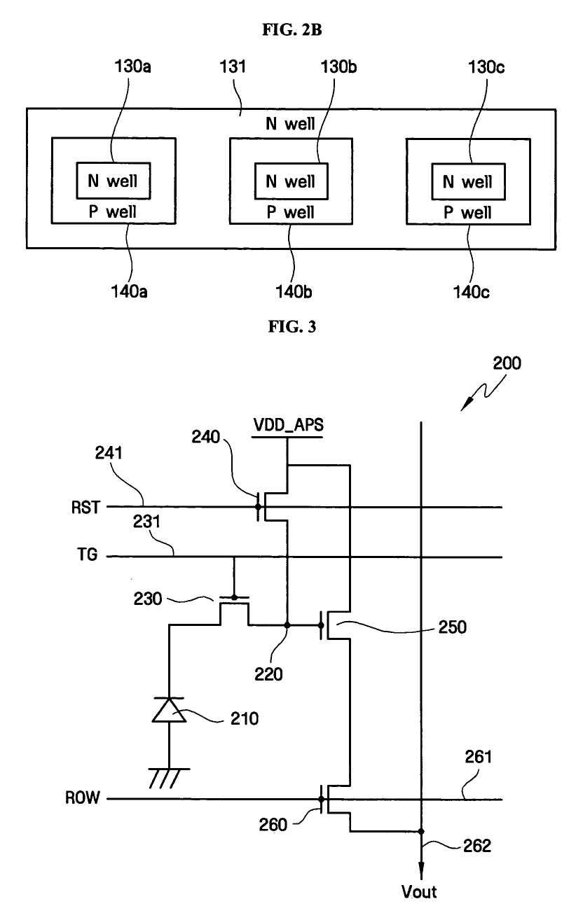

FIG. 2A is a sectional view illustrating a semiconductor IC device 100 according to an example embodiment of the present invention, and FIG. 2B is a plan view of the semiconductor IC device 100 shown in FIG. 2.

Referring to FIGS. 2A and 2B, the semiconductor IC device 100 may include an analog circuit 102, a digital circuit 104 and an image sensing circuit 106, which may be formed on a semiconductor substrate 101.

The analog circuit 102 may include a first N well 130a, a first deep P well 120a formed under the first N well 130a, and a first protective P well 140a formed to surround side surfaces of the first N well 130a. The digital circuit 104 may include a second N well 130b, a second deep P well 120b formed under the second N well 130b, and a second protective P well 140b formed to surround side surfaces of the second N well 130b. The image sensing circuit 106 may include an APS array 150, a third deep P well 120c formed under the APS array 150, and a third protective P well 140c formed to surround side surfaces of the APS array 150. As stated above, the analog circuit 102, which may include the CDS 50 and the ADC 60, may be formed in the first N well 130a, the first deep P well 120a and the first protective P well 140a. The digital circuit, which may include the timing generator 20, the row decoder 30, the row driver 40, the latch 70 and the column decoder 80, may be formed in the second N well 130b, the second deep P well 120b and the second protective P well 140b. The image sensing circuit 106, which may include the APS array 150, may be formed in the third N well 130c, the third deep P well 120c and the third protective P well 140c.

According to an example embodiment of the present invention, the semiconductor IC device 100 may be formed on the semiconductor substrate 101, and the semiconductor substrate 101 may be a silicon wafer or a silicon epitaxial layer, for example. In addition, the semiconductor substrate 101 may include an N-type or a P-type impurity. In FIG. 2A, an example embodiment of the present invention is described having an N-type semiconductor substrate 101.

Deep P wells 120a, 120b and 120c may be formed in the semiconductor substrate 101 to have a depth from a top surface of the N-type semiconductor substrate 101. The deep P wells 120a, 120b and 120c may be formed by implanting a P-impurity, for example, boron (B) ions, into the N-type semiconductor substrate 101. The deep P wells 120a, 120b and 120c may be formed to a depth of about 2 to about 12 μm from the top surface of the semiconductor substrate according to an example embodiment of the present invention. More specifically, the deep P wells may be formed to a depth of about 2 to about 3 μm, from the top surface of the semiconductor substrate 101. The deep P wells 120a, 120b and 120c may include a first deep P well 120a, a second deep P well 120b and a third deep P well 120c, which may correspond to the analog circuit 102, the digital circuit 104 and the image sensing circuit 106, respectively. The impurity may be implanted into the deep P wells 120a, 120b and 120c at a dose of about 2×10¹² atoms/cm². The deep P wells 120a, 120b and 120c may electrically isolate the analog circuit 102, the digital circuit 104 and the image sensing circuit 104 from one another, and may prevent the respective circuits 102, 104 and 106 from being significantly affected by a substrate power supply voltage VDD_sub.

The first N well 130a may be formed on the first deep P well 120a, and the first protective P well 140a for protecting the analog circuit 102 may be formed on the first deep P well 120a to surround the first N well 130a. The first N well 130a may be connected to an analog power supply voltage VDD_A, which may be an external power supply for the analog circuit 102. The external power supply for the analog circuit 102 may supply an analog power supply voltage VDD_A within the range of about 2.5 to about 3.5 V.

The second N well 130b may be formed on the second deep P well 120b. Further, the second protective P well 140b for protecting the digital circuit 104 may be formed on the deep P well 120b to surround the second N well 130b. The second N well 130b may be connected to a digital power supply voltage VDD_D, which may be a power supply for the digital circuit 104. The power supply for the digital circuit 104 may supply a digital power supply voltage VDD_D with in range of about 1 to about 2 V.

The APS array 150 may be formed on the third deep P well 120c. Further, the third protective P well 140c for protecting the APS array 150 may be formed on the third deep P well 120c to surround the APS array 150. The APS array 150 may be connected to an image sensing power supply voltage VDD_APS, which may be a power supply for the APS array 150. The power supply voltage VDD_APS for the APS array 150 may supply a voltage within a range of about 2 to 3V. The third protective P well 140c may be connected to an image sensing ground voltage GND.

The first, second and third protective P wells 140a, 140b and 140c may be isolated from one another by an N-type substrate well 131, which may serve to electrically isolate the analog circuit 102, the digital circuit 104 and the image sensing circuit 106 from one another. The N-type substrate well 131 may be connected to a substrate power supply voltage VDD_sub. The substrate power supply voltage may be within a range of about 2.5 to about 3.5 V.

For the first N well 130a, the second N well 130b and the N-type substrate well 131, phosphorous (P) may be used as the impurity at a dose of 2×10¹³ atoms/cm². The first N well 130a, the second N well 130b and the N-type substrate well 131 may be formed to have a predetermined depth of about 0.5 to about 2 μm from the top surface of the semiconductor substrate 101.

The first protective P well 140a, the second protective P well 140b and the third protective P well 140c may be formed by using boron (B) as the impurity, and a dose of the impurity may be about 3×10¹³ atoms/cm². The first protective P well 140a, the second protective P well 140b and the third protective P well 140c may extend from the top surface of the semiconductor substrate 101 toward the first deep P well 120a, the second deep P well 120b and the third deep P well 120c, respectively, thereby electrically isolating the first N well 130a, the second N well 130b and the APS array 150 from the semiconductor substrate 101.

According to an example embodiment of the present invention, by using the first through third deep P wells 120a, 120b and 120c and the corresponding first through third protective P wells 140a, 140b and 140c, the first and second N wells 130a and 130b and the APS array 150, which may be supplied with voltages from different external power supply sources VDD_A, VDD_D and VDD_APS, are electrically isolated from one another, which may reduce and/or minimize noise among the respective circuits 102, 104 and 106. The first through third deep P wells 120a, 120b and 120c and the corresponding protective P wells 140a, 140b and 140c, may form PN junctions together with the semiconductor substrate 101 having an N-type dopant. A depletion region may be formed in each PN junction, which is reversely biased. The depletion region may serve as a noise barrier in the respective circuits 102, 104 and 106.

An image sensing circuit included in a semiconductor IC device according to an example embodiment of the present invention will now be described in more detail with reference to FIGS. 3 through 5.

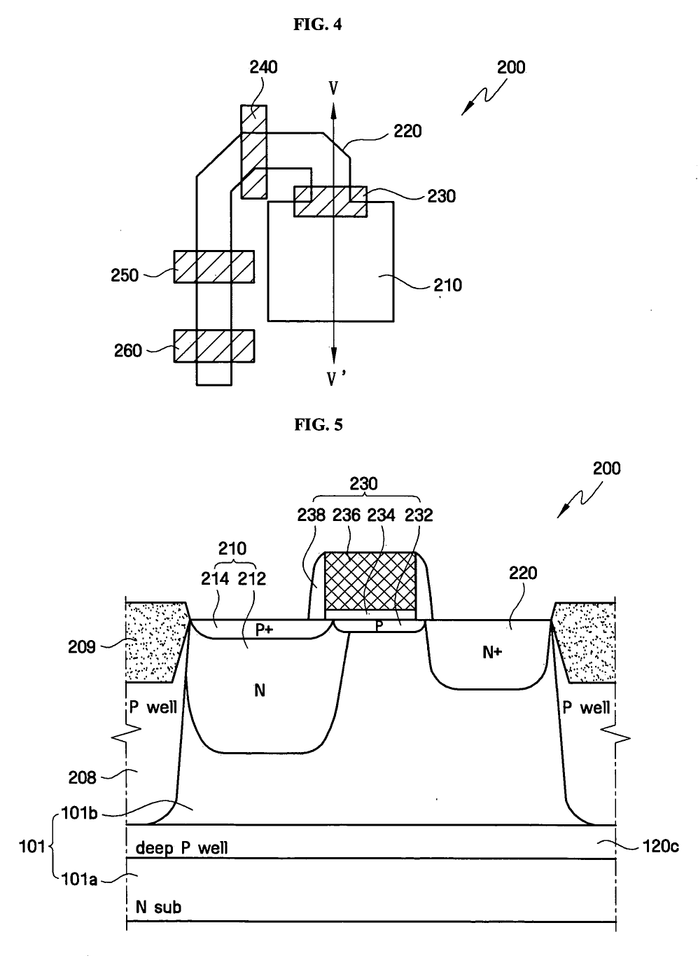

FIG. 3 is a circuit diagram illustrating each pixel of an image sensing circuit according to an example embodiment of the present invention; FIG. 4 is a schematic plan view of the pixel shown in FIG. 3; and FIG. 5 is a cross-sectional view illustrating the pixel of the image sensing circuit, taken along a line V-V′ of FIG. 4.

Referring to FIGS. 3 and 4, each pixel 200 of the image sensing circuit may include a photoelectric converter 210, a charge detector 220, a charge transfer unit 230, a reset unit 240, an amplifier 250, and a selector 260. As shown in FIG. 3, the pixel 200 according to an example embodiment of the present invention may include four transistors. However, the number of transistors included in the pixel 200 may vary according to an example embodiment of the present invention. For example, the pixel may include five transistors.

The photoelectric converter 210 may absorb incident light and accumulate charges corresponding to amount of the incident light. The photoelectric converter 210 may be implemented as a photodiode, a photo transistor, a photo gate, a pinned photo diode, or a combination thereof, for example.

The charge detector 220 may be implemented as a floating diffusion region, and may receive the charges accumulated in the photoelectric converter 210. Because the charge detector 220 may have a parasitic capacitance, the charges may be cumulatively stored. The charge detector 220 may be electrically connected to a gate of the amplifier 250, and may control the function of the amplifier 250.

The charge transfer unit 230 may transfer charges from the photoelectric converter 210 to the charge detector 220. The charge transfer unit 230 may include one transistor and may be controlled by a charge transfer signal TG.

The reset unit 240 may periodically reset the charge detector 220. A source of the reset unit 240 may be connected to the charge detector 220, and a drain of the reset unit 240 may be connected to the image sensing power supply voltage VDD_APS. Further, the reset unit 240 may be driven in response to a reset signal RST.

The amplifier 250 may be combined with a constant current source (not shown) disposed outside the pixel 200 and may act as a source follower buffer amplifier, which may offer a voltage to a vertical signal line 262 in response to the voltage of the charge detector 220. A source of the amplifier 250 may be connected to a drain of the selector 260, and a drain of the amplifier 250 may be connected to the image sensing power supply voltage VDD_APS.

The selector 260 may select the pixel 200 to be read for each row. The selector 260 may be driven in response to a selection signal ROW and a source thereof may be connected to the vertical signal line 262.

The charge transfer unit 230, the reset unit 240 and drive signal lines 231 and 261 of the selector 260 may extend in a row direction, i.e., in a transverse direction, so that pixels for the same row may be substantially simultaneously driven.

Referring to FIG. 5, the pixel 200 of the image sensing circuit according to an example embodiment of the present invention may include the semiconductor substrate 101, the deep well 120c, an isolation well 208, a device isolation region 209, the photoelectric converter 210, the charge detector 220, and the charge transfer unit 230. For the sake of convenient explanation, the example embodiment of the present invention illustrated in FIG. 5 is described with regard to a pinned photo diode as the photoelectric converter 210, but it is to be understood that the invention is not limited by the example embodiment of the present invention in FIG. 5.

The semiconductor substrate 101 has a first conductivity type, for example, N-type, and may be divided into a lower substrate region 101a and an upper substrate region 101b by the deep well 120c of a second conductivity type, e.g., P-type. An example embodiment of the present invention as illustrated in FIG. 5 is described with regard to the semiconductor substrate 101 that includes an N-type semiconductor substrate 101.

The deep well 120c may form a potential barrier to reduce and/or prevent charges generated at a lower substrate region 101a in a region of the semiconductor substrate 101 from entering the photoelectric converter 210 and may promote electron-hole recombination, which may reduce crosstalk between pixels due to, for example, a random drift of charges.

The deep well 120c may be formed to a depth of about 2 to about 12 am from a top surface of the semiconductor substrate 101. The depth of about 2 to about 12 μm substantially corresponds to an absorption length of red or near infrared region light in silicon. The smaller the depth of the deep well 120c formed from the top surface of the semiconductor substrate 101, the greater the diffusion protection effect may be, which may result in reduced crosstalk. Further, in a case of performing the shallow ion implantation process of the deep well 120c, a region of the photoelectric converter 210 may also become shallow. In this case, the deep region of the semiconductor substrate 101 may have a low sensitivity with respect to incident light having a relatively long wavelength, for example, a red wavelength. Accordingly, the position of the deep well 120c may vary according to wavelength regions of the incident light.

The device isolation region 209 may define an active region formed in the upper substrate region 101b. The device isolation region 209 may include a Field OXide (FOX) formed by using a LOCal Oxidation of Silicon (LOCOS) method and/or a Shallow Trench Isolation (STI) formed by a STI method.

Under the device isolation region 209, a second conductivity type, for example P-type, isolation well 208 may be formed. The isolation well 208 may isolate a plurality of photodiodes from each other. In order to reduce the horizontal crosstalk between the photodiodes 212, the isolation well 208 may be formed deeper than the photodiode 212 or may be formed to connect to the deep well 120c, as shown in FIG. 5.

The photoelectric converter 210 may include the N-type photodiode 212 formed in the semiconductor substrate 101, a P+-type pinning layer 214 and the upper substrate region 101b under the photodiode 212.

The photodiode 212 may have charges accumulated in proportion to the amount of the incident light, and the pinning layer 214 may prevent dark current by reducing electron-hole pairs (EHPs), which may be thermally generated. In more detail, the dark current of the image sensing circuit may be caused by surface degradation of a photodiode. The surface degradation may result from formation of dangling silicon bonds and/or defects associated with etching stress, which may occur in the course of forming gates and/or spacers. Accordingly, the photodiode 212 may be formed at a deep location of the upper substrate region 101b and the pinning layer 214 may then be formed, so that among the EHPs thermally generated on the top surface of the upper substrate 10b, positive charges may be diffused into the grounded semiconductor substrate 101 via a P+-type pinning layer 214 and negative charges may be recombined with the positive charges in the pinning layer 214, thereby removing the EHPs.

In addition, because the photodiode 212 may be separated a distance apart from the deep well 120c, the photodiode 212 may act as a region for photoelectrically converting the upper substrate region 101b disposed thereunder, which may enhance color sensitivity with respect to incident light having a relatively long wavelength, for example, a red wavelength.

The photodiode 212 may have a maximum impurity concentration in a range of about 1×10¹⁵ to 1×10¹⁸ atoms/cm², while the pinning layer 214 may have an impurity concentration in a range of about 1×10¹⁷ to 1×10²⁰ atoms/cm². However, it is noted that example embodiments of the present invention are not limited to the concentration and the position of the impurity which may be dependent upon a manufacturing process and a design of the semiconductor IC device 100.

The charge detector 220 formed in the semiconductor substrate 101 may receive the charges accumulated in the photoelectric converter 210 via the charge transfer unit 230.

The charge transfer unit 230 may include an impurity region 232, a gate insulation layer 234, a gate electrode 236 and a spacer 238. The impurity region 232 may reduce and/or prevent dark current generated without regard to an image sensed during turn-off status of the charge transfer unit 230. The impurity region 232 may be formed by implanting the semiconductor substrate 101 with boron (B) and/or boron fluoride (BF₂).

The gate insulation layer 234 may be formed of SiO₂, SiON, SiN, Al₂O₃, Si₃N₄, GexOyNz, GexSiyOz or other high dielectric materials. Examples of the high dielectric materials include HfO₂, ZrO₂, Ta₂O₅, hafnium silicate, zirconium silicate and a combination thereof. The gate insulation layer 234 may have a multi-layered structure including at least two material layers selected from the above. The gate insulation layer 234 may have a thickness of about 5 to about 100 angstroms.

The gate electrode 236 may be formed as a polysilicon layer, a metal layer, a titanium nitride (TiN) layer, a metal silicide layer or a combination thereof, for example. The metal layer may include a layer of tungsten (W), platinum (Pt) and/or aluminum (Al). The metal silicide layer may be formed using a refractory metal, such as Co, Ni, Ti, Hf, Pt or the like, as a main metal. Further, the gate electrode 236 may be formed by sequentially stacking a conductive polysilicon layer and a metal silicon layer, or stacking a conductive polysilicon layer, a metal layer, or the like, but it should be understood that example embodiments of the present invention are not limited to the above.

The spacer 238 formed on, for example, both side walls of the gate electrode 236 may be formed of a silicon nitride (SiN) layer, for example.

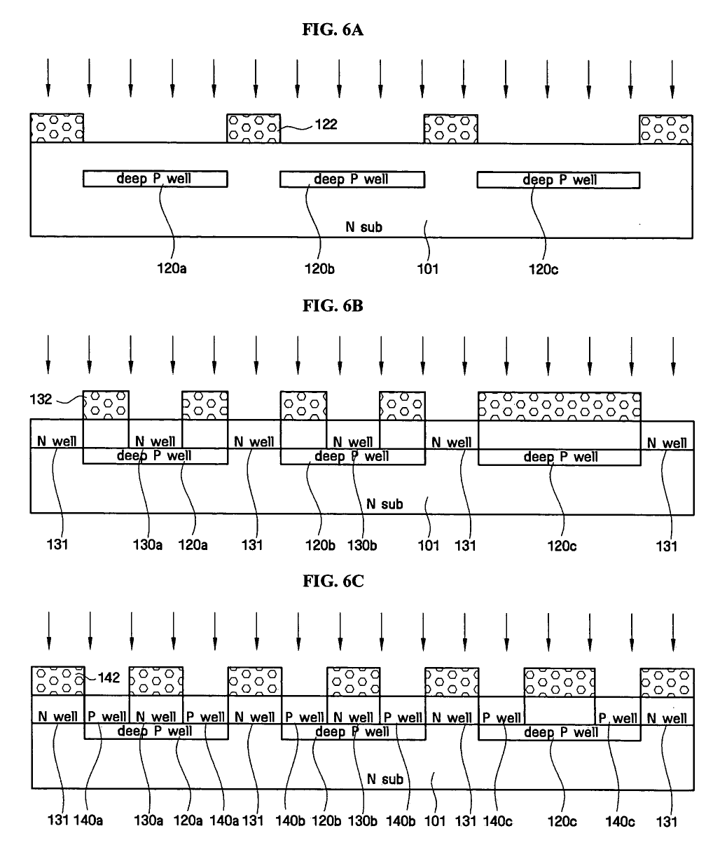

FIGS. 6A through 6C are cross-sectional views illustrating a method of fabricating a semiconductor IC device according to an example embodiment of the present invention.

Referring to FIG. 6A, a first photoresist pattern 122 may be formed on a semiconductor substrate 101, and a P-type impurity may be selectively implanted into the semiconductor substrate 101 to form first, second and third deep P wells 120a, 120b and 120c. For example, boron (B) is implanted into the semiconductor substrate 101 at a dose of 2×10¹² atoms/cm² to a depth of 2-12 μm from a top surface of the semiconductor substrate 101. The first photoresist pattern 122 may be removed after the impurities are implanted.

Referring to FIG. 6B, a second photoresist pattern 132 may be formed on the semiconductor substrate 101, and an N-type impurity may be implanted into the semiconductor substrate 101 to form first and second N wells 130a and 130b and an N-type substrate well 131. The first and second N wells 130a and 130b and the N-type substrate well 131 may be formed between the top surface of the semiconductor substrate 101 and each of the first, second and third deep P wells 120a, 120b and 120c, respectively. For example, in order to form the first and second N wells 130a and 130b and the N-type substrate well 131, phosphorous (P) may be implanted into the semiconductor substrate 101 to a depth of about 0.5 to about 2 μm from the top surface of the semiconductor substrate 101 at a dose of about 2×10¹³ atoms/cm². Thereafter, the second photoresist pattern 132 may be removed.

Referring to FIG. 6C, a third photoresist pattern 142 may be formed on the semiconductor substrate 101, and a P-type impurity may be selectively implanted into the semiconductor substrate 101 to form first, second and third protective P wells 140a, 140b and 140c. The first, second, and third protective P wells 140a, 140b and 140c may extend from the top surface of the semiconductor substrate 101 toward the first, second and third deep P wells 120a, 120b and 120c, respectively, thereby electrically isolating the first and second N wells 130a, 130b and the APS array 150 from the semiconductor substrate 101.

For example, the first, second and third protective P wells 140a, 140b and 140c are formed by implanting boron (B) at a dose of 3×10¹³ atoms/cm². Then, the third photoresist pattern 142 may be removed.

The order of forming the wells shown in FIGS. 6B and 6C may be reversed.

Forming of the APS array 150 including the pixel 200 of the image sensing circuit shown in FIG. 5 on a portion of the semiconductor substrate 101 forms the semiconductor IC device 100 shown in FIGS. 2B and 2C. In FIG. 5, the portion of the semiconductor substrate 101 may be surrounded by the third protective P well 140c.

In subsequent processes, which may include insulation layer formation, contact hole formation and/or metal interconnect formation, conventional methods may be employed.

While in an example embodiment of the present invention the semiconductor IC device 100 is shown as formed on the N-type semiconductor substrate, the present invention is not limited thereto. That is, a semiconductor IC device 100 according to an example embodiment of the present invention may be formed on a P-type semiconductor substrate using the same well structure.

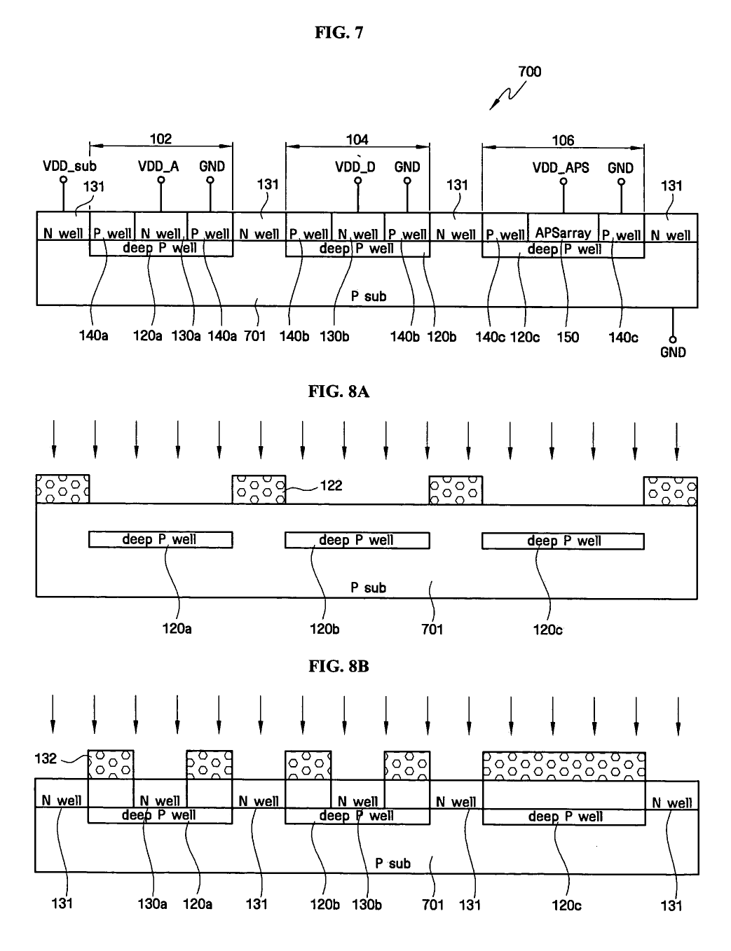

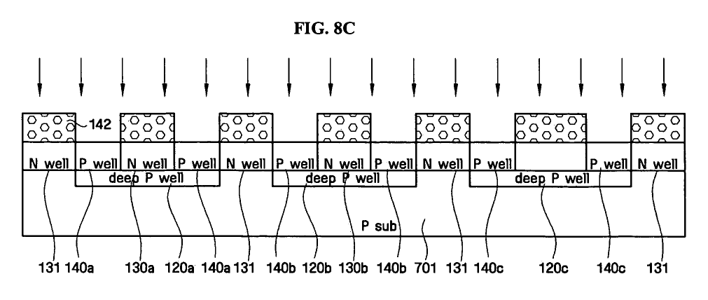

Referring to FIGS. 7 through 8C, a semiconductor IC device according to an example embodiment of the present invention will now be described in detail.

FIG. 7 is a cross-sectional view illustrating a semiconductor IC device 700 according to an example embodiment of the present invention, and FIG. 8A to FIG. 8C are cross-sectional views illustrating a method of fabricating the semiconductor IC device 700 according to an example embodiment of the present invention. Components having the same function as described with respect to the example embodiments of the present invention shown in FIGS. 1 through 6C are respectively identified by the same reference numerals and the description of the like components will not be repeated for the sake of brevity.

The semiconductor IC device 700 according to an example embodiment of the present invention as shown in FIG. 7 has basically same structure as the semiconductor IC devices described with respect to previous example embodiments of the present invention except that the semiconductor IC device 700 is formed on the P-type semiconductor substrate 701. The semiconductor IC device 700 according to an example embodiment of the present invention may include an analog circuit 102, a digital circuit 104 and an image sensing circuit 106 formed on the P-type semiconductor substrate 701.

The semiconductor substrate 701 may be a silicon wafer and/or a silicon epitaxial layer, for example. The P-type semiconductor substrate 701 may be connected to a ground voltage GND for the semiconductor substrate 701.

Protective P wells 140a, 140b and 140c, and deep P wells 120a, 120b and 120c in the semiconductor substrate 701 may be connected to a ground voltage GND, and first and second N wells 130a and 130b and an APS array 150 surrounded thereby may be electrically isolated from one another.

According to an example embodiment of the present invention, the N wells 130a and 130b and the APS array 150 supplied with different voltages from different power supply sources VDD_A, VDD_D and VDD_APS, respectively, are electrically isolated from one another, which may reduce noise from the respective circuits 102, 104 and 106.

Further, according to an example embodiment of the present invention, because the semiconductor substrate 701 has a P-type conductivity type, the protective P wells 140a, 140b and 140c may not need to extend toward the deep P wells 120a, 120b and 120c, respectively, for the purpose of electrically isolating the first and second N wells 130a and 130b and the APS array 150 from one another. For example, the protective P wells 140a, 140b and 140c may be formed in the semiconductor substrate 701 to a depth within a range of about 0.5 to 2 μm from the top surface of the semiconductor substrate 701.

As described above, according to example embodiments of the present invention, the semiconductor IC device and the method of fabricating the same may be implemented using either the N-type or the P-type semiconductor substrate while having the same well structure, and the digital circuit, the analog circuit and the image sensing circuit may be supplied with voltages from the different external power supply sources. Further, noise due to the different external power supply sources may be reduced and/or minimized according to example embodiments of the present invention.

In concluding the detailed description of example embodiments of the present invention, those skilled in the art will appreciate that many variations and modifications may be made to the example embodiments of the present invention without substantially departing from the principles of the present invention. Therefore, the disclosed example embodiments of the present invention are used in a generic and descriptive sense only and not for purposes of limitation.

What is claimed is:

1. A semiconductor integrated circuit (IC) device, comprising:
first, second and third deep wells of a first conductivity type formed in a semiconductor substrate, and electrically isolated from one another;
first and second wells of a second conductivity type and an active pixel sensor (APS) array formed between a top surface of the semiconductor substrate and the first, second and third deep wells, respectively, and connected to different power supply voltages, respectively; and
first, second and third protective wells of the first conductivity type formed in the semiconductor substrate and surrounding side surfaces of the first and second wells and the APS array, respectively.

2. The semiconductor IC device according to claim 1, wherein an analog circuit is formed in each of the first well and the first protective well, a digital circuit is formed in each of the second well and the second protective well, and an image sensing circuit is formed in each of the APS array and the third protective well.

3. The semiconductor IC device according to claim 2, wherein the first, second and third protective wells are connected to a ground voltage (GND).

4. The semiconductor IC device according to claim 2, wherein the analog circuit includes a correlated double sampler (CDS) for sampling an electrical signal from the APS array.

5. The semiconductor IC device according to claim 2, wherein the digital circuit includes a timing generator for providing a timing signal and a control signal, or a decoder.

6. The semiconductor IC device according to claim 1, wherein the first, second and third deep wells are formed to a depth within a range of about 2 to about 12 μm from the top surface of the semiconductor substrate.

7. The semiconductor IC device according to claim 6, wherein the first, second and third deep wells are ion implantation regions doped at a dose of about 2×10¹² atoms/cm².

8. The semiconductor IC device according to claim 1, wherein the substrate has the second conductivity type, and the first, second and third protective wells are formed to extend from the top surface of the semiconductor substrate toward the first, second and third deep wells, respectively.

9. The semiconductor IC device according to claim 8, wherein the semiconductor substrate includes an N-type dopant and is connected to a substrate power supply voltage VDD_sub.

10. The semiconductor IC device according to claim 1, wherein the semiconductor substrate has the first conductivity type and the first, second and third protective wells are formed to a depth within a range of about 0.5 to about 2 μm from the top surface of the semiconductor substrate.

11. The semiconductor IC device according to claim 10, wherein the semiconductor substrate includes a P-type dopant and is connected to a ground voltage (GND).

12. The semiconductor IC device according to claim 1, further comprising a substrate well of the second conductivity type formed between each of the first, second and third protective wells, for electrically isolating the first, second and third protective wells from one another.

13. A method of fabricating a semiconductor integrated circuit (IC) device, comprising:
forming first, second and third deep wells of a first conductivity type in a semiconductor substrate so the first, second and third deep wells are electrically isolated from one another; and
forming first and second wells of a second conductivity type and an active pixel sensor (APS) array between a top surface of the semiconductor substrate and the first, second and third deep wells, respectively, so that the first and second wells and the APS are surrounded by first, second and third protective wells, respectively, the first and second wells and the APS are connected to different power supply voltages.

14. The method of claim 13, wherein the forming of the first and second wells and the APS array comprises:
forming the first and second wells and the APS array between the semiconductor substrate and the first, second and third deep wells, respectively; and
forming the first, second and third protective wells in the semiconductor substrate in such a way to surround side surfaces of the first and second wells and the APS array.

15. The method of claim 14, further comprising:
forming a substrate well of the second conductivity type between the first, second and third protective wells for electrically isolating the first, second and third protective wells from one another.

16. The method of claim 13, further comprising:
forming an analog circuit in the first well and the first protective well;
forming a digital circuit in the second well and the second protective well; and
forming an image sensing circuit in the APS array and the third protective well.

17. The method of claim 16, wherein the first, second and third protective wells are connected to a ground voltage (GND).

18. The method of claim 16, wherein the analog circuit has a correlated double sampler (CDS) for sampling an electrical signal from the APS array.

19. The method of claim 16, wherein the digital circuit has a timing generator for providing a timing signal and a control signal, and a decoder.

20. The method of claim 13, wherein the first, second and third deep wells are formed to a depth within a range of about 2 to about 12 μm from the top surface of the semiconductor substrate.

21. The method of claim 20, wherein the first, second and third deep wells are ion implantation regions doped at a dose of about 2×10¹² atoms/cm².

22. The method of claim 13, wherein the semiconductor substrate has the second conductivity type, and the first, second and third protective wells are formed to extend from the top surface of the semiconductor substrate toward the first, second and third deep wells, respectively.

23. The method of claim 22, wherein the semiconductor substrate includes an N-type dopant and is connected to a substrate power supply voltage VDD_sub.

24. The method of claim 13, wherein the semiconductor substrate has the first conductivity type and the first, second and third protective wells are formed to a depth within a range of about 0.5 to about 2 μm from the top surface of the semiconductor substrate.

25. The method of claim 24, wherein the semiconductor substrate includes a P-type dopant and is connected to a ground voltage (GND).
